(19) United States
(12) Patent Application Publication
(10) Pub. No.: US 2023/0215786 A1
(43) Pub. Date: Jul. 6, 2023

(54) PLANAR MULTI-CHIP DEVICE

(71) Applicant: HARVATEK CORPORATION, Hsinchu City (TW)

(72) Inventors: CHIN-JUI LIANG, Hsinchu City (TW); Hui-Yen Huang, HSINCHU CITY (TW); FENG-HUI CHUANG, New Taipei City (TW); PING-LUNG WANG, HSINCHU CITY (TW)

(21) Appl. No.: 17/691,184

(22) Filed: Mar. 10, 2022

(30) Foreign Application Priority Data
Dec. 30, 2021 (TW) 110149572

(51) Int. Cl. H01L 23/495; H01L 21/48; H01L 25/065

(52) U.S. Cl. CPC H01L 23/49537; H01L 23/49575; H01L 21/4825; H01L 25/0655; H01L 2225/06555

(57) ABSTRACT

A planar multi-chip device includes a base structure and a plurality of functional chips. The base structure has a central area and a peripheral area outside the central area. The central area includes a first conductive portion arranged therein. The peripheral area includes a plurality of second conductive portions and a plurality of third conductive portions arranged therein and separated from each other. The functional chips are arranged on the base structure, and each of the functional chips has a portion located on and electrically connected to the first conductive portion. At least two of the functional chips are configured to be in signal communication with each other via at least one of the third conductive portions.

### CROSS-REFERENCE TO RELATED PATENT APPLICATION

This application claims the benefit of priority to Taiwan Patent Application No. 110149572, filed on Dec. 30, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor device, and more particularly to a planar multi-chip device, which is suitable for use in handheld and miniature electronic products such as digital cameras, smartphones, tablets, and satellite navigation systems.

### BACKGROUND OF THE DISCLOSURE

In the information society of today, electronic products on the market are required to have high performance, multiple functions, and a thin and lightweight design. Therefore, many package designs for integrating chips of the same or different types into a single package such as multi-chip modules (MCM) and system-in-package (SIP) have been developed. However, such package designs need to be capable of accommodating complex layouts for electrical connections (e.g., interior and exterior electrical connections) within limited space, which is highly reliant upon superior manufacturing processes and is difficult to be achieved by the average process.

A lead frame is one of the commonly used packaging substrates for multi-chip integration. As chips continue to progress toward miniaturization, the structure of the lead frame must be changed accordingly to provide a higher density, a finer structure, and a greater quantity of leads. Once part of the lead frame is improperly arranged, the lead frame may cause a short circuit and may not be able to provide sufficient supporting strength. Furthermore, while a vertical stacking of chips is one of the most effective structures for multi-chip integration, in which through silicon vias (TSV) are used to provide vertical interconnections between the chips, the making of through-silicon vias requires expensive processing equipment and a large number of consumables, such that costs concerns have become one of the foremost considerations when seeking improvement in the relevant industry.

### SUMMARY OF THE DISCLOSURE

The present disclosure focuses on realizing a wireless and TSV-free module package with multiple chips, by virtue of “a first conductive portion having a maximized effective area is disposed at the center of a base structure to serve as a common electrical contact, and a plurality of functional chips are configured to be in signal communication via a plurality of third conductive portions distributed around the first conductive portion.”

In one aspect, the present disclosure provides a planar multi-chip device that includes a base structure and a plurality of functional chips. The base structure has a central area and a peripheral area outside the central area. The central area includes a first conductive portion arranged therein. The peripheral area includes a plurality of second conductive portions and a plurality of third conductive portions arranged therein and separated from each other. The functional chips are arranged on the base structure, and each of the functional chips has a portion located on and electrically connected to the first conductive portion. At least two of the functional chips are configured to be in signal communication with each other via at least one of the third conductive portions.

In certain embodiments, the second conductive portions and the third conductive portions each extend into the peripheral area from a position close to the central area.

In certain embodiments, the base structure further has at least one supporting portion that has a first end fixed to the peripheral area and a second end connected to the first conductive portion.

In certain embodiments, the peripheral area of the base structure has a plurality of corner positions. The third conductive portions are at least divided into a first group of third conductive portions and a second group of third conductive portions. The first group of third conductive portions extend to one of the corner positions from a position close to one side of the central area, and the second group of third conductive portions extend to another one of the corner positions from a position close to another one side of the central area. The at least one supporting portion extends to the rest of the corner positions from the central area.

In certain embodiments, the first conductive portion is a single lead or multi-lead electrode. The second conductive portions and the third conductive portions are each a lead. The at least one supporting portion is a connecting rod.

In certain embodiments, the first conductive portion includes a plurality of conductive bodies separated from each other and fixed to the second end of the at least one supporting portion.

In certain embodiments, the first conductive portion has a plurality of hollow structures.

In certain embodiments, the planar multi-chip device further includes a protective layer that isolates the functional chips from an outside environment.

In certain embodiments, the planar multi-chip device further includes a metal shielding layer disposed on the protective layer.

In certain embodiments, the protective layer has a lateral surface around the functional chips and an upper surface perpendicular to and connected to the lateral surface. The metal shielding layer covers the lateral surface and the upper surface of the protective layer.

In certain embodiments, the planar multi-chip device further includes a heat dissipating member that is disposed between the functional chips and the metal shielding layer and isolated from the outside environment by the protective layer.

In certain embodiments, the functional chips are respectively and electrically connected to the first conductive portion, the second conductive portions, and the third conductive portions via a plurality of conductive bumps.

In certain embodiments, a quantity of the second conductive portions is 4n, where n is an integer greater than 2. A quantity of the functional chips is not less than 2. A quantity of the conductive bumps located on the second conductive portions is at least equal to the quantity of the second conductive portions. A quantity of the conductive bumps located on the third conductive portions is at least a quarter of the quantity of the second conductive portions. A quantity of the conductive bumps located on the first conductive portion is at least one third of a total number of the conductive bumps.

One of the beneficial effects of the subject matter provided by the present disclosure is that, in the planar multi-chip device, by virtue of “each of the functional chips has a portion located on and electrically connected to the first conductive portion, and at least two of the functional chips are configured to be in signal communication with each other via at least one of the third conductive portions,” a close interconnection between the functional chips and a wireless package can be achieve based on general process capability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a base structure of a planar multi-chip device according to a first embodiment of the present disclosure;

FIG. 2 is a top partial view of the planar multi-chip device according to the first embodiment of the present disclosure;

FIG. 3 is a planar view of the planar multi-chip device according to the first embodiment of the present disclosure;

FIG. 4 is a planar view of a planar multi-chip device according to a second embodiment of the present disclosure;

FIG. 5 is a planar view of a planar multi-chip device according to a third embodiment of the present disclosure; and

FIG. 6 is another planar view of the planar multi-chip device according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

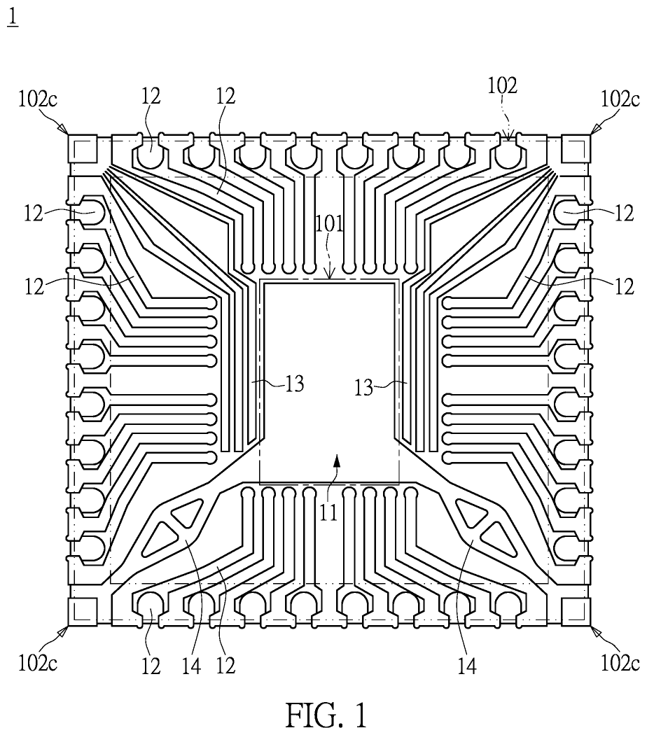

Referring to FIG. 1 to FIG. 3, a first embodiment of the present disclosure provides a planar multi-chip device Z that mainly includes a base structure 1 and a plurality of functional chips 2. The functional chips 2 are disposed on the base structure 1. In use, the base structure 1 can provide power or signal transmission paths extending outwards from the functional chips 2, and the functional chips 2 can be in signal communication with each other via the base structure 1.

The details of the base structure 1 and the connection relationship between the base structure 1 and the functional chips 2 will be described with reference to the accompanying figures.

The base structure 1 can be a lead frame or a package substrate and has a central area 101 and a peripheral area 102 outside the central area 101. In the present embodiment, the central area 101 includes a first conductive portion 11 arranged therein. The peripheral area 102 includes a plurality of second conductive portions 12 and a plurality of third conductive portions 13 arranged therein and separated from each other. In practice, the first conductive portion 11 can serve as a common ground contact or at least one other common electrical contact and provide support and positioning for the functional chips 2. The functional chips 2 each have a portion located on and electrically connected to the first conductive portion 11. Furthermore, the second conductive portions 12 can each serve as a signal transmission bridge between a chip and an external device (e.g., a printed circuit board). The third conductive portions 13 can each serve as a communication bridge between chips. At least two of the functional chips 2 can be in signal communication with each other via at least one of the third conductive portions 13.

More specifically, the second conductive portions 12 are arranged around the first conductive portion 11, and are preferably arranged in a radial distribution around the first conductive portion 11 as a center. Furthermore, the third conductive portions 13 are also arranged around the first conductive portion 11, and are preferably arranged in a symmetrical distribution with respect to the first conductive portion 11 as the center. The extreme ends of the third conductive portions 13 are formed into free ends by cutting, which are suspended and not connected to other components. In consideration of spatial layout requirements, the second conductive portions 12 and the third conductive portions 13 can each have a bent portion.

In order to increase the support of the first conductive portion 11, the base structure 1 can further include at least one supporting portion 14 that has a first end 141 fixed to the peripheral area 102 and a second end 142 connected to the first conductive portion 11. The third conductive portions 13 can be at least divided into a first group of third conductive portions 13 and a second group of third conductive portions 13 that are symmetrically disposed at two opposite sides of the first conductive portion 11. Furthermore, as shown in FIG. 1, the peripheral area 102 of the base structure 1 can have a plurality of corner positions 102c (FIG. 1 shows that the base structure 1 has a rectangular contour and four corner positions 102c). The first group of third conductive portions 13 can extend to one of the corner positions 102c from a position close to one side of the central area 101 (e.g., the left side of the first conductive portion 11), and the second group of third conductive portions 13 can extend to another one of the corner positions 102c from a position close to another one side of the central area 101 (e.g., the right side of the first conductive portion 11). The at least one supporting portion 14 can extend to the rest of the corner positions 102c from the central area 101. The above description is for exemplary purposes only and is not intended to limit the scope of the present disclosure.

In practice, the first conductive portion 11 can be a single lead or multi-lead electrode. The second conductive portions 12 and the third conductive portions 13 can each be a lead. The at least one supporting portion 14 can be a connecting rod. However, such examples are not intended to limit to the present disclosure.

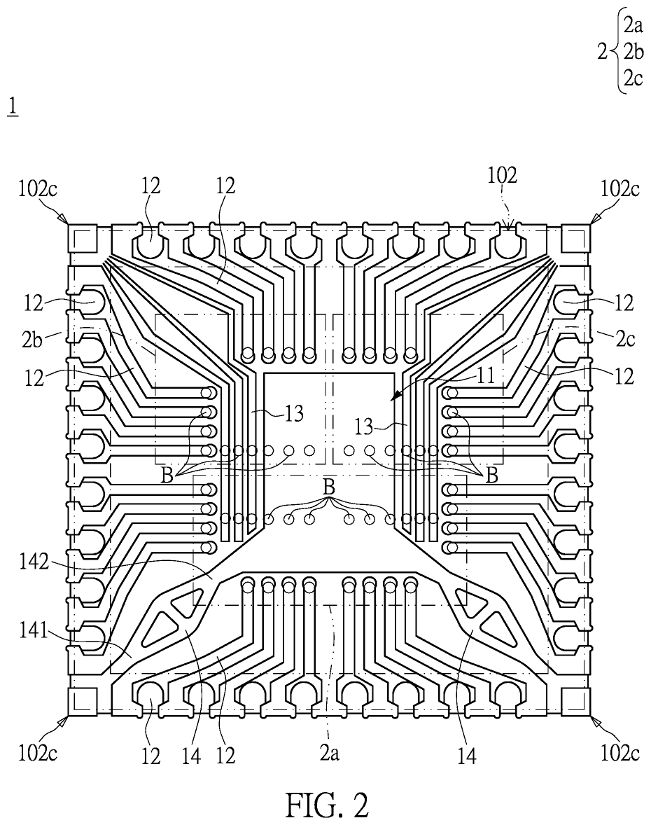

In the above structure, as shown in FIG. 2, a quantity of the functional chips 2 can be three, namely a first functional chip 2a, a second functional chip 2b, a third functional chip 2c, which can respectively be a primary functional chip and two secondary functional chips. The first functional chip 2a, the second functional chip 2b, and the third functional chip 2c are placed side by side with each other. The first functional chip 2a and the second functional chip 2b can be in signal communication with each other via the first group of third conductive portions 13, and the first functional chip 2a and the third functional chip 2c can be in signal communication with each other via the second group of third conductive portions 13. However, the present disclosure is not limited to the above-mentioned example (i.e., an example of module package with three chips). In practice, a quantity of the functional chips 2 and the design of the base structure 1 can be changed according to the design idea of the present disclosure.

In certain embodiments, a quantity of the functional chips 2 is four which are arranged in a two-by-two array. The third conductive portions 13 can be divided into three groups and arranged around the first conductive portion 11, so as to establish communication bridges between the four functional chips 2. The first conductive portion 11 (e.g., a single lead or multi-lead electrode) can be supported by only one supporting portion 14.

In practice, the functional chips 2 are respectively and electrically connected to the first conductive portion 11, the second conductive portions 12, and the third conductive portions 13 via a plurality of conductive bumps B (e.g., solder balls). The conductive bumps B can provide the shortest vertical interconnection paths for the functional chips 2. Therefore, the functional chips 2 and the base structure 1 can work with each other to realize one or more main functions of an applied electronic product. It is worth mentioning that only a portion of the conductive bumps B are shown in FIG. 2 so as to prevent the lines in FIG. 2 from becoming more complicated and confusing.

Specific examples of the functional chips 2 include NOR Flash, NAND Flash, DRAM, low power SRAM, pseudo SRAM, power IC, MCU, and CPU chips. However, such examples are not intended to limit to the present disclosure. Moreover, other electronic components such as a capacitor and an inductor can be included in addition to the functional chips 2.

Preferably, the planar multi-chip device Z satisfies the following relationships (1) through (4):
(1) a quantity of the second conductive portions 12 is 4n, where n is an integer greater than 2;
(2) a quantity of the functional chips 2 is not less than 2;
(3) a quantity of the conductive bumps B located on the second conductive portions 12 is at least equal to the quantity of the second conductive portions 12, and a quantity of the conductive bumps B located on the third conductive portions 13 is at least a quarter of the quantity of the second conductive portions 12; and
(4) a quantity of the conductive bumps B located on the first conductive portion 11 is at least one third of a total number of the conductive bumps B.
   Therefore, the planar multi-chip device Z can have an increased integration density and reduced pattern pitches (i.e., pitches in a pattern formed by the arrangement of the first conductive portion 11, the second conductive portions 12, and the third conductive portions 13), which can help to reduce a device size, enhance device functionality, and reduce costs.

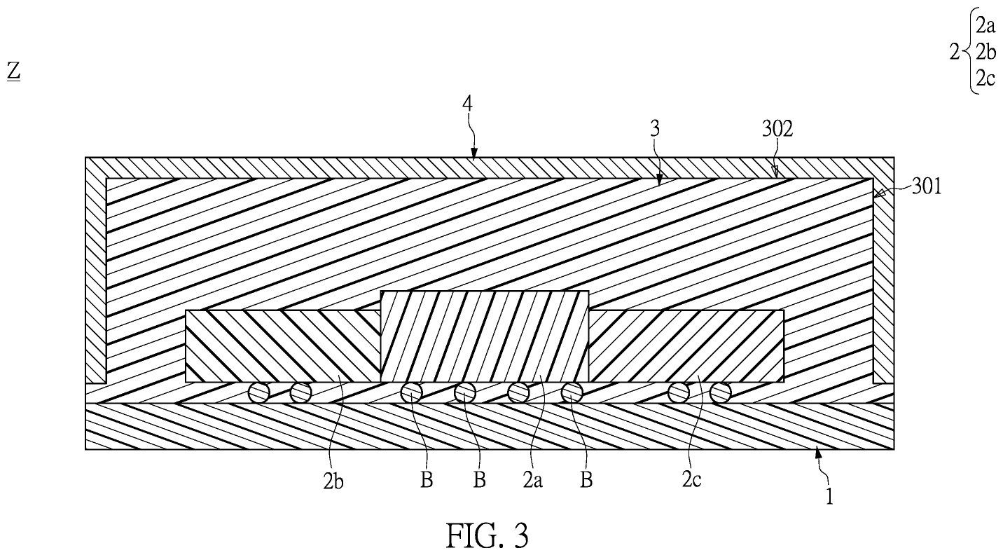

As shown in FIG. 3, the planar multi-chip device Z can further include a protective layer 3 covering the functional chips 2 so as to isolate the functional chips 2 from an outside environment, thereby reducing negative impacts caused by environmental factors (e.g., humidity) and preventing the functional chips 2 from being physically damaged. The protective layer 3 has a lateral surface 301 around the functional chips 2 and an upper surface 302 perpendicular to and connected to the lateral surface 301. In practice, the protective layer 3 can be formed from a molding compound including epoxy resin or silicone, and it can further cover a portion or the entirety of the base structure 1.

The planar multi-chip device Z can further include a metal shielding layer 4 disposed on the protective layer 3, thereby preventing the functional chips 2 from being subjected to electromagnetic interference. In practice, the metal shielding layer 4 can cover the lateral surface 301 and the upper surface 302 of the protective layer 3, but the present is not limited thereto.

### Second Embodiment

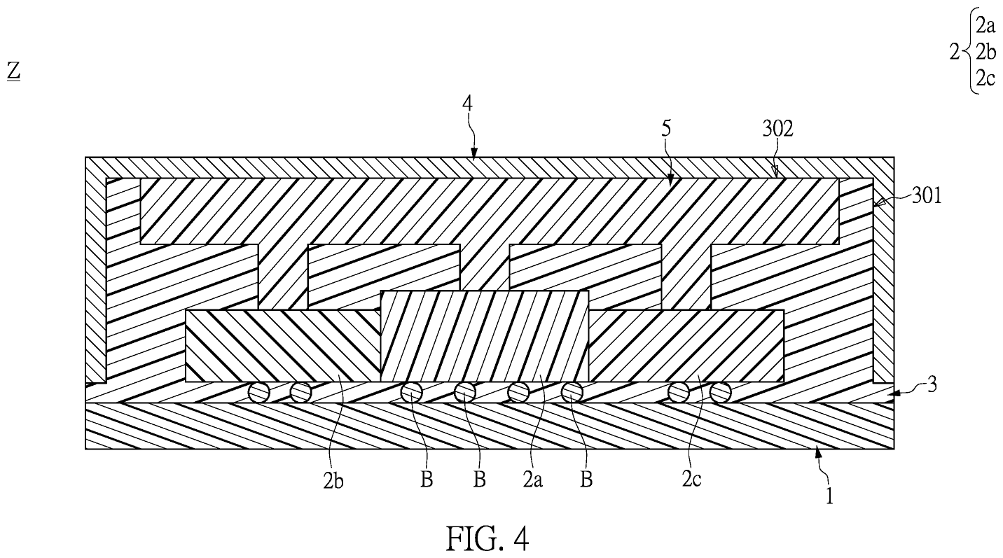

Referring to FIG. 4, a second embodiment of the present disclosure provides a planar multi-chip device Z. As show in FIG. 4, the planar multi-chip device Z further includes a heat dissipating member 5, in addition to a base structure 1, a plurality of functional chips 2, a protective layer 3, and a metal shielding layer 4 illustrated in the first embodiment.

In the present embodiment, the base structure 1 has a central area 101 and a peripheral area 102 around the central area 101. In the present embodiment, the central area 101 includes a first conductive portion 11 arranged therein. The peripheral area 102 includes a plurality of second conductive portions 12 and a plurality of third conductive portions 13 arranged therein and separated from each other. The functional chips 2 are disposed on the base structure 1 and each have a portion located on and electrically connected to the first conductive portion 11. At least two of the functional chips 2 are configured to be in signal communication with each other via at least one of the third conductive portions 13. The protective layer 3 isolates the functional chips 2 from an outside environment. The metal shielding layer 4 is disposed on the protective layer 3. The heat dissipating member 5 is disposed between the functional chips 2 and the metal shielding layer 4 and isolated from the outside environment by the protective layer 3.

In practice, one portion of the heat dissipating member 5 is in contact with the functional chips 2, and another one portion of the heat dissipating member 5 is in contact with the metal shielding layer 4. The heat dissipating member 5 can be, but is not limited to being, formed from one of the following metals and their alloys: gold, silver, copper, aluminum, tin and nickel. Therefore, the functional chips 2 can be in signal communication with each other via the base structure 1, and heat generated by the functional chips 2 can be quickly dissipated to the outside through the heat dissipating member 5.

The relevant technical details mentioned in the first embodiment are still valid in the present embodiment and will not be repeated here for the sake of brevity. Similarly, the technical details mentioned in the present embodiment can also be applied in the first embodiment.

### Third Embodiment

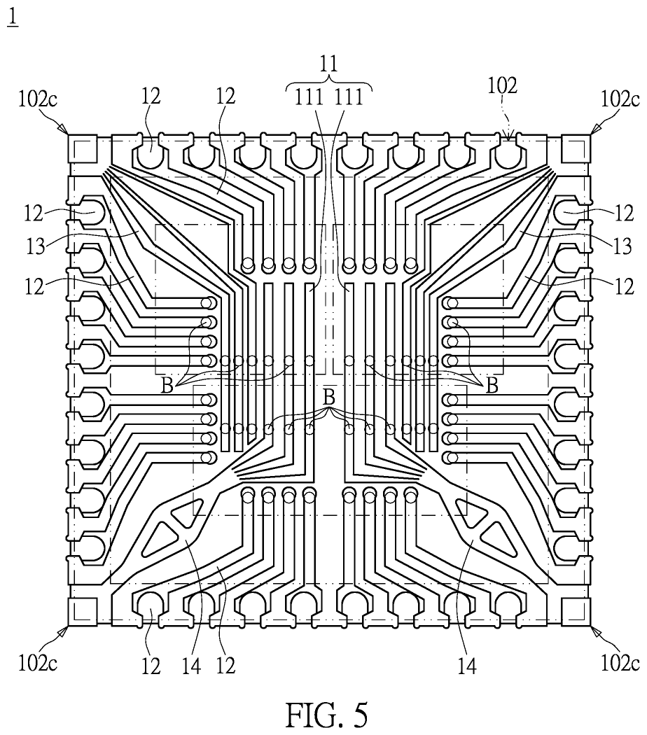

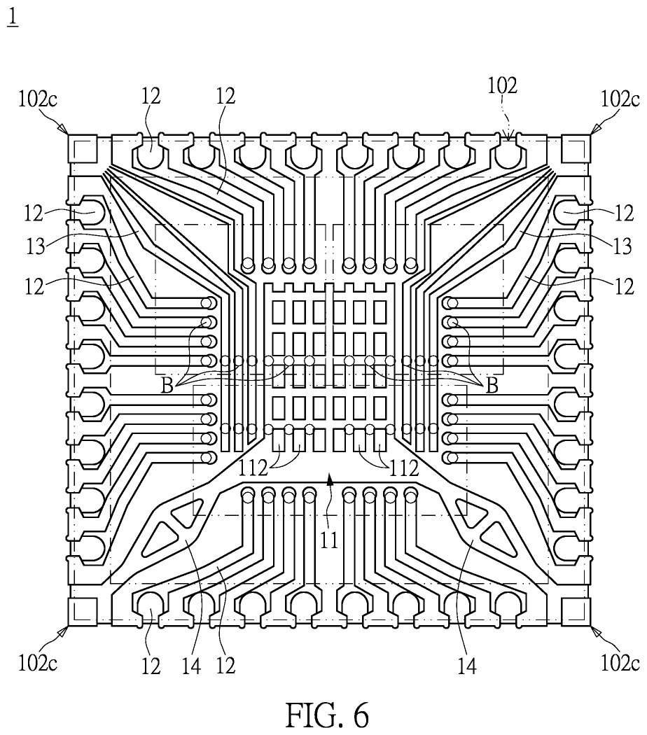

Referring to FIG. 5 and FIG. 6, a third embodiment of the present disclosure provides a planar multi-chip device Z. As show in FIG. 5 and FIG. 6, a first conductive portion 11 of a base structure 1 can be patterned. More specifically, the first conductive portion 11 can include a plurality of conductive bodies 111 (e.g., conductive pads as shown in FIG. 5) separated from each other that are fixed to a second end 142 of at least one supporting portion 14. In practice, the conductive bodies 111 can be distributed at a certain interval along a transverse or longitudinal direction (e.g., a length direction). Alternatively, the first conductive portion 11 can have a plurality of hollow structures 112 (e.g., hollow holes or grooves as shown in FIG. 6).

The relevant technical details mentioned in the first and second embodiments are still valid in the present embodiment and will not be repeated here for the sake of brevity. Similarly, the technical details mentioned in the present embodiment can also be applied in the first and second embodiments.

### Beneficial Effects of the Embodiments

In the planar multi-chip device of the present disclosure, by virtue of “each of the functional chips has a portion located on and electrically connected to the first conductive portion, and at least two of the functional chips are configured to be in signal communication with each other via at least one of the third conductive portions,” a close interconnection between the functional chips and a wireless package can be achieve based on general process capability.

More specifically, in the planar multi-chip device of the present disclosure, the conductive portions, and the conductive bumps satisfy the following relationships (1) through (4):
(1) a quantity of the second conductive portions is 4n, where n is an integer greater than 2;
(2) a quantity of the functional chips is not less than 2;
(3) a quantity of the conductive bumps located on the second conductive portions is at least equal to the quantity of the second conductive portions, and a quantity of the conductive bumps located on the third conductive portions is at least a quarter of the quantity of the second conductive portions; and
(4) a quantity of the conductive bumps located on the first conductive portion is at least one third of a total number of the conductive bumps.
   Therefore, an integration density can be increased and pattern pitches (i.e., pitches in a pattern formed by the arrangement of the first conductive portion, the second conductive portions, and the third conductive portions) can be reduced, which can help to reduce a device size, enhance device functionality, and reduce costs.

More specifically, the planar multi-chip device of the present disclosure can further include a heat dissipating member disposed between the functional chips and the metal shielding layer and protected by the protective layer. Accordingly, the heat dissipation problem of an electronic product can be solved to ensure normal operation of the electronic product, thereby extending the lifespan of the electronic product.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A planar multi-chip device, comprising:
a base structure having a central area and a peripheral area outside the central area, wherein the central area includes a first conductive portion arranged therein, and the peripheral area includes a plurality of second conductive portions and a plurality of third conductive portions arranged therein, the plurality of second conductive portions being separate from the plurality of third conductive portions; and
a plurality of functional chips arranged on the base structure, wherein each of the functional chips has a portion located on and electrically connected to the first conductive portion, and at least two of the functional chips are configured to be in signal communication with each other via at least one of the third conductive portions.

2. The planar multi-chip device according to claim 1, wherein the second conductive portions and the third conductive portions each extend into the peripheral area from a position close to the central area.

3. The planar multi-chip device according to claim 2, wherein the base structure further includes at least one supporting portion that has a first end fixed to the peripheral area and a second end connected to the first conductive portion.

4. The planar multi-chip device according to claim 3, wherein the peripheral area of the base structure has a plurality of corner positions, the third conductive portions are at least divided into a first group of third conductive portions and a second group of third conductive portions, the first group of third conductive portions extend to one of the corner positions from a position close to one side of the central area, and the second group of third conductive portions extend to another one of the corner positions from a position close to another one side of the central area; wherein the at least one supporting portion extends to the rest of the corner positions from the central area.

5. The planar multi-chip device according to claim 4, wherein the first conductive portion is a single lead or multi-lead electrode, the second conductive portions and the third conductive portions are each a lead, and the at least one supporting portion is a connecting rod.

6. The planar multi-chip device according to claim 4, wherein the first conductive portion includes a plurality of conductive bodies separated from each other and fixed to the second end of the at least one supporting portion.

7. The planar multi-chip device according to claim 4, wherein the first conductive portion has a plurality of hollow structures.

8. The planar multi-chip device according to claim 1, further comprising a protective layer that isolates the functional chips from an outside environment.

9. The planar multi-chip device according to claim 8, further comprising a metal shielding layer disposed on the protective layer.

10. The planar multi-chip device according to claim 9, wherein the protective layer has a lateral surface around the functional chips and an upper surface perpendicular to and connected to the lateral surface, and the metal shielding layer covers the lateral surface and the upper surface of the protective layer.

11. The planar multi-chip device according to claim 9, further comprising a heat dissipating member that is disposed between the functional chips and the metal shielding layer and isolated from the outside environment by the protective layer.

12. The planar multi-chip device according to claim 1, wherein the functional chips are respectively and electrically connected to the first conductive portion, the second conductive portions, and the third conductive portions via a plurality of conductive bumps.

13. The planar multi-chip device according to claim 12, wherein a quantity of the second conductive portions is 4n, n being an integer greater than 2, a quantity of the functional chips is not less than 2, a quantity of the conductive bumps located on the second conductive portions is at least equal to the quantity of the second conductive portions, a quantity of the conductive bumps located on the third conductive portions is at least a quarter of the quantity of the second conductive portions, and a quantity of the conductive bumps located on the first conductive portion is at least one third of a total number of the conductive bumps.
